(19) United States
(12) Patent Application Publication
(10) Pub. No.: US 2016/0056797 A1
(43) Pub. Date: Feb. 25, 2016

(54) REGISTER CIRCUIT SYSTEM AND SOLID-STATE IMAGING DEVICE

(71) Applicant: Kabushiki Kaisha Toshiba, Minato-ku (JP)

(72) Inventors: Takayoshi KIMURA, Yokohama (JP); Kyoichi TAKENAKA, Yokohama (JP)

(73) Assignee: Kabushiki Kaisha Toshiba, Minato-ku (JP)

(21) Appl. No.: 14/795,420

(22) Filed: Jul. 9, 2015

(30) Foreign Application Priority Data
Aug. 20, 2014 (JP) 2014-167943

(51) Int. Cl. H03K 3/012; H04N 5/374

(52) U.S. Cl. CPC H03K 3/012; H04N 5/3743

(57) ABSTRACT

According to one embodiment, a register circuit system includes a first register circuit, a step-down circuit, and a second register circuit. The step-down circuit generates a second power voltage from a first power voltage. The second power voltage is a power voltage of a potential level lower than the first power voltage. The second register circuit is supplied with the second power voltage from the step-down circuit. The first register circuit keeps holding data during a period of time in which the step-down circuit is stopping the generating of the second power voltage.

### CROSS-REFERENCE TO RELATED APPLICATIONS

This application is based upon and claims the benefit of priority from Japanese Patent Application No. 2014-167943, filed on Aug. 20, 2014; the entire contents of which are incorporated herein by reference.

### FIELD

Embodiments described herein relate generally to a register circuit system and a solid-state imaging device.

### BACKGROUND

In the past, an integrated circuit (IC) device including a register circuit and a step-down circuit has been known. The register circuit operates by a supply of a voltage of a potential level lower than a power voltage supplied to the IC device. The step-down circuit generates an internal power voltage of a low potential level from the power voltage supplied to the IC device. The step-down circuit supplies the internal power voltage to the register circuit. The register circuit holds data while the internal power voltage is being supplied. A system including the register circuit and the step-down circuit is appropriately referred to a “register circuit system.”

When the supply of the internal power voltage is interrupted, the data being held by the register circuit is lost. In the register circuit system, even when the IC device enters the standby state, the step-down circuit continuously generates the internal power voltage in order to keep holding the data. The IC device causes the step-down circuit to continuously operate even in the standby state, and thus it is difficult to reduce current consumption in the register circuit system.

### BRIEF DESCRIPTION OF THE DRAWINGS

FIG. 1 is a block diagram illustrating a configuration of an IC device with which a register circuit system according to a first embodiment is equipped;

FIG. 2 is a schematic diagram illustrating a configuration of a low voltage register circuit illustrated in FIG. 1;

FIG. 3 is a schematic diagram illustrating a configuration of a high voltage register circuit illustrated in FIG. 1;

FIG. 4 is a diagram for describing transmission and reception of data between the low voltage register circuit illustrated in FIG. 2 and the high voltage register circuit illustrated in FIG. 3; and

FIG. 5 is a block diagram illustrating a schematic configuration of a solid-state imaging device according to a second embodiment.

### DETAILED DESCRIPTION

In general, according to one embodiment, a register circuit system includes a first register circuit, a step-down circuit, and a second register circuit. The first register circuit is supplied with a first power voltage. The first register circuit holds data. The step-down circuit generates a second power voltage from the first power voltage. The second power voltage is a power voltage of a potential level lower than the first power voltage. The second register circuit is supplied with the second power voltage from the step-down circuit. The second register circuit holds data. The first register circuit keeps holding the data during a period of time in which the step-down circuit is stopping the generating of the second power voltage.

Exemplary embodiments of a register circuit system and a solid-state imaging device will be described below in detail with reference to the accompanying drawings. The present invention is not limited to the following embodiments.

### First Embodiment

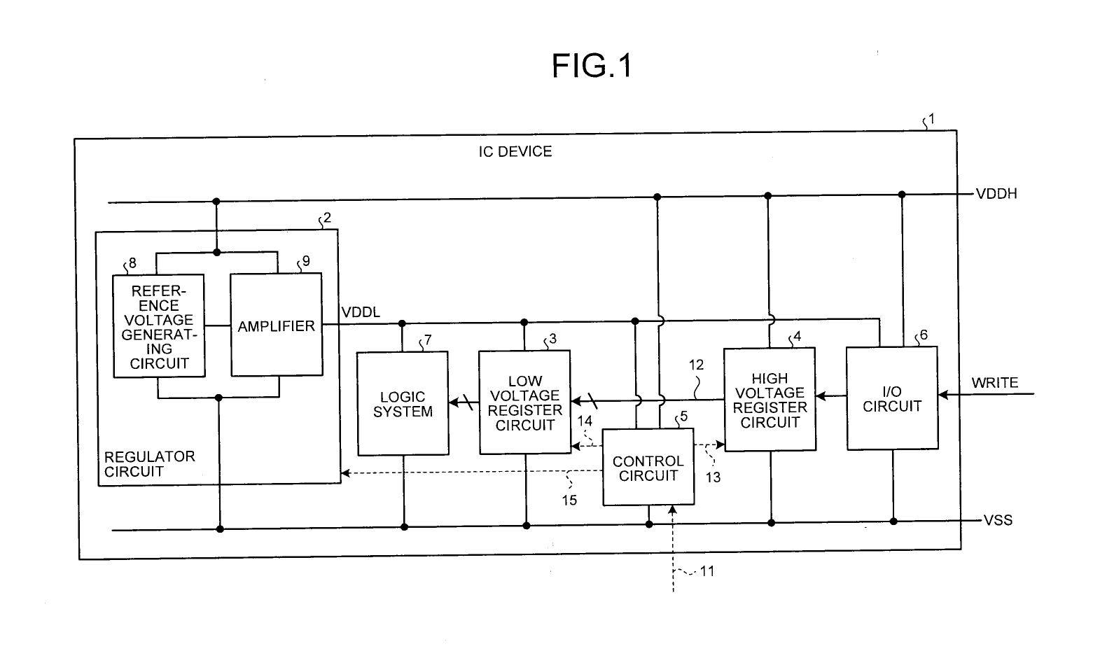

FIG. 1 is a block diagram illustrating a configuration of an IC device with which a register circuit system according to a first embodiment is equipped. An IC device 1 includes a regulator circuit 2, a low voltage register circuit 3, a high voltage register circuit 4, a control circuit 5, an input/output (I/O) circuit 6, and a logic system 7. The circuits configuring the IC device 1 are mounted on a common chip. The regulator circuit 2, the low voltage register circuit 3, the high voltage register circuit 4, and the control circuit 5 configure the register circuit system.

The IC device 1 is supplied with a power voltage (VDDH) of one system from an internal power source. The VDDH is a first power voltage of a high potential. The regulator circuit 2 is a step-down circuit. The regulator circuit 2 generates an internal power voltage (VDDL) from the VDDH. The VDDL is a second power voltage of a low potential. The VDDL is a power voltage of a potential level lower than the first power voltage.

The IC device 1 includes a circuit to which the VDDH is supplied and a circuit to which the VDDL is supplied. An analog circuit that deals with an analog signal is mainly supplied with the VDDH. A logic circuit that deals with a digital signal is mainly supplied with the VDDL. The IC device 1 is equipped with the analog circuit and the logic circuit.

The regulator circuit 2 includes a reference voltage generating circuit 8 and an amplifier 9. The reference voltage generating circuit 8 and the amplifier 9 operate using the VDDH as a power source. The reference voltage generating circuit 8 generates a reference voltage. The amplifier 9 amplifies a difference between the reference voltage from the reference voltage generating circuit 8 and a feedback voltage of the VDDL. The regulator circuit 2 outputs the VDDL generated through the amplification performed by the amplifier 9.

The high voltage register circuit 4 operates using the VDDH as a power source. The high voltage register circuit 4 holds written data when the VDDH is being supplied. The high voltage register circuit 4 is a first register circuit.

The low voltage register circuit 3 operates using the VDDL as a power source. The low voltage register circuit 3 holds written data when the VDDL is being supplied. The low voltage register circuit 3 is a second register circuit.

The control circuit 5 controls operations of the regulator circuit 2, the low voltage register circuit 3, and the high voltage register circuit 4. The control circuit 5 operates using the VDDH and the VDDL as a power source. The I/O circuit 6 is an I/O interface of the IC device 1. The I/O circuit 6 operates using the VDDH and the VDDL as a power source.

The logic system 7 performs operation processing of data read from the low voltage register circuit 3. The logic system 7 operates using the VDDL as a power source. The low voltage register circuit 3, the high voltage register circuit 4, the control circuit 5, the I/O circuit 6, the logic system 7, the reference voltage generating circuit 8, and the amplifier 9 are connected to a reference potential (VSS).

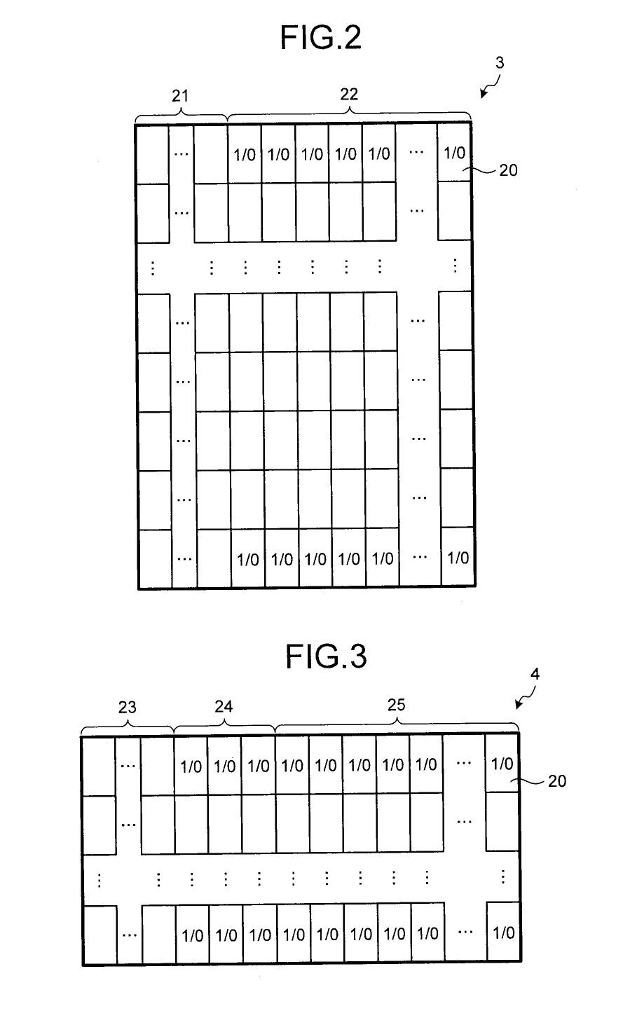

FIG. 2 is a schematic diagram illustrating a configuration of the low voltage register circuit illustrated in FIG. 1. The low voltage register circuit 3 includes a plurality of storage elements 20. The storage element 20 is, for example, a flip-flop circuit. The storage element 20 holds one-bit information.

The low voltage register circuit 3 includes an address area 21 and a data area 22. The data area 22 is an area in which data is held. The address area 21 is an area in which an address is held. The address indicates a position at which data is held in the low voltage register circuit 3.

FIG. 3 is a schematic diagram illustrating a configuration of the high voltage register circuit illustrated in FIG. 1. The high voltage register circuit 4 includes a plurality of storage elements 20. The storage element 20 is, for example, a flip-flop circuit. The storage element 20 holds one-bit information. The high voltage register circuit 4 includes an address area 23, an address information area 24, and a data area 25.

The data area 25 is an area in which data is held. The address information area 24 is an area in which address information is held. The address information is information indicating an address in the low voltage register circuit 3. The address area 23 is an area in which an address is held. The address indicates a position at which data and address information are held in the high voltage register circuit 4.

The low voltage register circuit 3 is assumed to be able to hold N-bit data. The high voltage register circuit 4 is assumed to be able to hold M-bit data including address information. N is larger than M. A memory capacity of the data area 25 and the address information area 24 is larger than a memory capacity of the data area 22. Alternatively, the memory capacity of the data area 25 and the address information area 24 of the high voltage register circuit may be equal to or smaller than the memory capacity of the data area 22 of the low voltage register circuit 3. In this case, N is equal to or larger than M.

The storage element 20 of the low voltage register circuit 3 includes a transistor for a low voltage. The circuit size of the low voltage register circuit 3 can be reduced using a small-sized transistor formed through a fine processing technique. The transistor is operable at a low voltage as its size is reduced. Thus, the power consumption of the low voltage register circuit 3 can be reduced.

Next, an operation of the IC device 1 will be described. Here, an operation when data is written in the IC device 1 will be described as an example. A register value is rewritten in the IC device 1 from the outside of the IC device 1 using a communication device. Data is transmitted from the outside of the IC device 1 to the IC device 1 using a communication device. The I/O circuit 6 receives data input to the IC device 1. The I/O circuit 6 transmits data input from the outside to the IC device 1 to the high voltage register circuit 4.

The high voltage register circuit 4 receives data from the I/O circuit 6. The data received by the high voltage register circuit 4 includes the address and the address information of the high voltage register circuit 4. The high voltage register circuit 4 stores the data and the address information at the position of the corresponding address. The address information is information indicating the address of the low voltage register circuit 3.

The high voltage register circuit 4 rewrites a value of a portion that is updated in the data received from the I/O circuit 6 among data being held in the high voltage register circuit 4. The data to be input to the high voltage register circuit 4 is not limited to one including the address information of the low voltage register circuit 3. The high voltage register circuit 4 may stores the data including the address information of the low voltage register circuit 3 at an arbitrary position.

The control circuit 5 transmits a control signal 13 to the high voltage register circuit 4. The high voltage register circuit 4 transmits transmission data 12 to the low voltage register circuit 3 in response to the control signal 13. The transmission data 12 includes information of the same content as the data and the address information stored in the high voltage register circuit 4. The control signal 13 is a signal to instruct transmission of the transmission data 12 to the low voltage register circuit 3.

The control circuit 5 transmits a control signal 14 to the low voltage register circuit 3. The control signal 14 is a signal to instruct reception of the transmission data 12. The low voltage register circuit 3 receives the transmission data 12 from the high voltage register circuit 4 in response to the control signal 14. The data received by the low voltage register circuit 3 includes the address information. The low voltage register circuit 3 stores the data at a position of an address indicated by the address information.

In the above-described way, the IC device 1 writes the data input from the outside in the low voltage register circuit 3. When the data is written in the low voltage register circuit 3, the high voltage register circuit 4 holds data of the same content as the data written in the low voltage register circuit 3. Thus, in the register circuit system, the low voltage register circuit 3 and the high voltage register circuit 4 hold common data.

The IC device 1 outputs the data being stored in the low voltage register circuit 3 according to an external request. A description of an operation of the IC device 1 when the data is read from the IC device 1 is omitted.

The IC device 1 is assumed to be able to switch an operation mode between an operation state serving as a first mode and a standby state serving as a second mode. The logic system 7 performs the operation processing in the operation state. The IC device 1 performs writing and reading of data in the operation state. The logic system 7 stops the operation processing in the standby state. The IC device 1 stops writing and reading of data in the standby state.

Upon receiving a mode switching signal 11 from the outside in the operation state, the IC device 1 switches the operation mode from the operation state to the standby state. The mode switching signal 11 is a signal to instruct the IC device 1 to switch the operation mode.

The control circuit 5 receives the mode switching signal 11. Upon receiving the mode switching signal 11 in the operation state, the control circuit 5 transmits a control signal 15 to give an operation stop instruction to the regulator circuit 2. The regulator circuit 2 stops generation of the VDDL in response to the control signal 15. As a result, in the register circuit system, when the IC device 1 is in the standby state, the operation of the regulator circuit 2 is stopped.

The supply of the VDDL to the low voltage register circuit 3, the control circuit 5, the I/O circuit 6, and the logic system 7 is interrupted. Further, in the IC device 1, in both the operation state and the standby state, the VDDH is continuously supplied.

Since the supply of the VDDL to the low voltage register circuit 3 is interrupted, the data held in the low voltage register circuit 3 is lost. On the other hand, since the VDDH is continuously supplied, the high voltage register circuit 4 keeps holding the data and the address information. Thus, the register circuit system can maintain the data written before the IC device 1 enters the standby state even during the standby state.

Upon receiving the mode switching signal 11 in the standby state, the control circuit 5 transmits a control signal 15 to give an operation resumption instruction to the regulator circuit 2. The control circuit 5 performs reception of the mode switching signal 11 and transmission of the control signal 15 using the VDDH as a power source.

The regulator circuit 2 resumes the generation of the VDDL in response to the control signal 15. The supply of the VDDL to the low voltage register circuit 3, the control circuit 5, the I/O circuit 6, and the logic system 7 is resumed.

Since the supply of the VDDL is resumed, the low voltage register circuit 3 enters a data writable state. The control circuit 5 transmits the control signal 13 to the high voltage register circuit 4. The control circuit 5 transmits the control signal 14 the low voltage register circuit 3 that is in the data writable state.

The high voltage register circuit 4 transmits the transmission data 12 to the low voltage register circuit 3 in response to the control signal 13. The transmission data 12 includes information of the same content as the data and the address information being stored in the high voltage register circuit 4.

The low voltage register circuit 3 receives the transmission data 12 from the high voltage register circuit 4 in response to the control signal 14. The low voltage register circuit 3 stores the data at a position of an address indicated by the address information in the data area 22. Thus, the register circuit system returns to the state in which the low voltage register circuit 3 and the high voltage register circuit 4 hold common data.

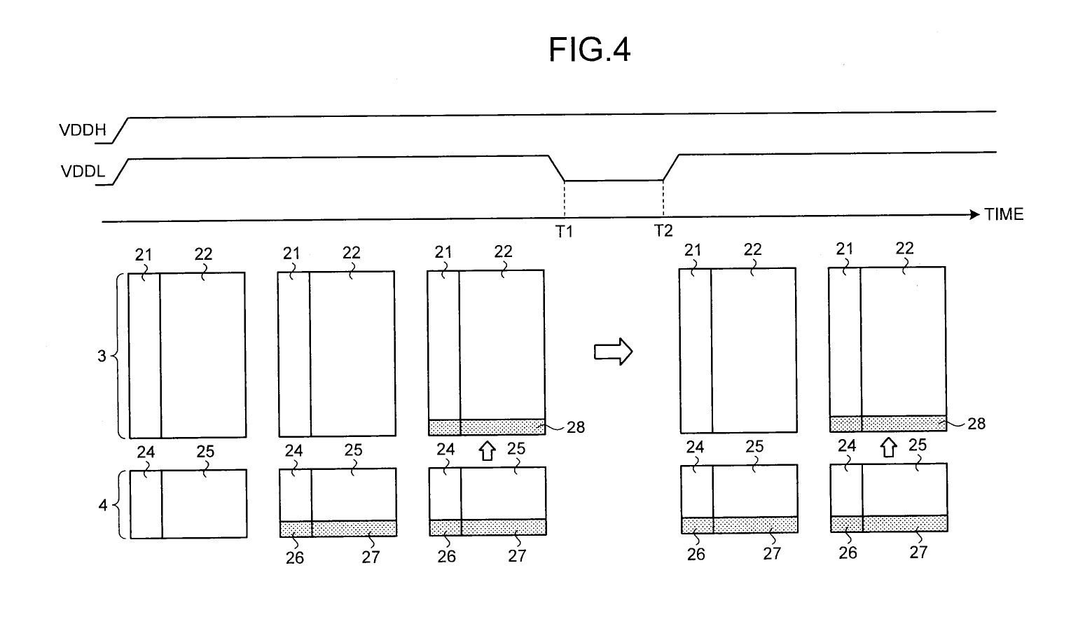

FIG. 4 is a diagram for describing transmission and reception of data between the low voltage register circuit illustrated in FIG. 2 and the high voltage register circuit illustrated in FIG. 3. In FIG. 4, the address area 23 of the high voltage register circuit 4 is not illustrated.

A first process is assumed to be performed in an initial state in which no data is written in both the low voltage register circuit 3 and the high voltage register circuit 4. In the first process, a value held by each of the storage elements 20 of the low voltage register circuit 3 and the high voltage register circuit 4 has an initial value. The initial value is either of 0 and 1.

A second process is assumed to be performed when data is input to the I/O circuit 6. In the register circuit system, in the second process, data 27 and address information 26 are written at an arbitrary address of the high voltage register circuit 4. The data 27 is written in the data area 25. The address information 26 is written in the address information area 24. The high voltage register circuit 4 stores the data 27 and the address information 26 at an arbitrary address.

Then, in a third process, the high voltage register circuit 4 transmits the transmission data 12 to the low voltage register circuit 3. The transmission data 12 includes information of the same content as the data 27 and the address information 26 stored in the high voltage register circuit 4. Data 28 of the same content as the data 27 is written in the low voltage register circuit 3. The data 28 is written in the data area 22. The low voltage register circuit 3 stores the data 28 at a position of the address area 21 indicated by the address information 26 included in the transmission data 12.

After the third process, the operation mode of the IC device 1 is switched from the operation state to the standby state at a certain time T1. Further, the operation mode of the IC device 1 is switched from the standby state to the operation state at T2 later than T1. The supply of the VDDL in the IC device 1 is interrupted during a period of time of T1 to T2 in which the IC device 1 is in the standby state. The supply of the VDDH to the IC device 1 is continued in both the operation state and the standby state.

Since the supply of the VDDL is interrupted during the period of time of T1 to T2, all values of the storage elements 20 of the low voltage register circuit 3 are returned to the initial value. Thus, the data 28 held in the low voltage register circuit 3 is lost. In the period of time of T1 to T2, the high voltage register circuit 4 continuously holds the data 27 and the address information 26. A process in the period of time of T1 to T2 is referred to as a fourth process.

Then, in a fifth process, the high voltage register circuit 4 transmits the transmission data 12 to the low voltage register circuit 3. The transmission data 12 includes information of the same content as the data 27 and the address information 26 being stored in the high voltage register circuit 4. The data 28 of the same content as the data 27 is written in the low voltage register circuit 3. The data 28 is written in the data area 22. The low voltage register circuit 3 stores the data 28 at a position indicated by the address information 26 included in the transmission data 12.

According to the first embodiment, the register circuit system includes the low voltage register circuit 3 and the high voltage register circuit 4. The size of the low voltage register circuit 3 can be reduced through the fine processing technique. The high voltage register circuit 4 is configured to have the memory capacity smaller than the memory capacity of the low voltage register circuit 3. The circuit size of the register circuit system can be reduced compared to the configuration in which data is held only in the high voltage register circuit 4. In the register circuit system, the memory capacity per unit area can be increased. Since the circuit size of the register circuit system can be reduced, the manufacturing cost can be reduced.

The register circuit system generates the VDDL from the VDDH of one system. In the register circuit system, even when the operation of the regulator circuit 2 is stopped, data can be continuously held. In the IC device 1, when it returns from the standby state, time and effort to read the same data as data read in the past from the outside can be saved. As data is written from the high voltage register circuit 4 to the low voltage register circuit 3, the IC device 1 can return to the state before it enters the standby state. In the IC device 1, compared to when data is read from the outside, a time necessary for the return from the standby state can be reduced. In the register circuit system, when the operation of the regulator circuit 2 is continued in the standby state, the current consumption can be significantly reduced.

Accordingly, the register circuit system and the IC device 1 have the advantage in that the current consumption can be reduced. The register circuit system and the IC device 1 can achieve both maintenance of data in the standby state and reduction in the current consumption.

In the register circuit system, data input to the I/O circuit 6 may be first stored in either of the high voltage register circuit 4 and the low voltage register circuit 3. In the register circuit system according to an embodiment, data from the I/O circuit 6 is stored in the high voltage register circuit 4 and then transmitted from the high voltage register circuit 4 to the low voltage register circuit 3. In this case, in the register circuit system, the data transmission and reception process can be performed more easily than when data is stored in the low voltage register circuit 3 and then transmitted to the high voltage register circuit 4.

### Second Embodiment

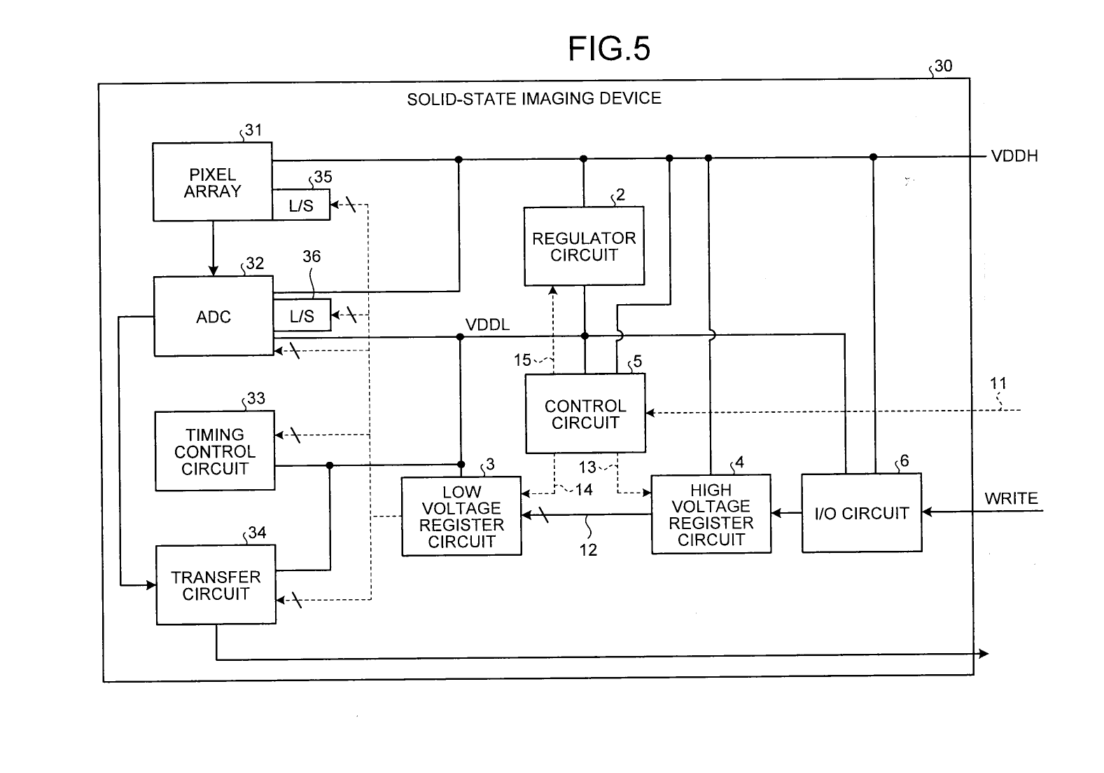

FIG. 5 is a block diagram illustrating a schematic configuration of a solid-state imaging device according to a second embodiment. A solid-state imaging device 30 includes the register circuit system according to the first embodiment. The same parts as in the first embodiment are denoted by the same reference numerals, and a duplicated description will be appropriately omitted.

The solid-state imaging device 30 images a subject image. The solid-state imaging device 30 includes a pixel array 31, an analog-to-digital converting circuit (ADC) 32, a timing control circuit 33, a transfer circuit 34, a register circuit system, and an I/O circuit 6. The register circuit system includes a regulator circuit 2, a low voltage register circuit 3, a high voltage register circuit 4, and a control circuit 5. The circuits configuring the solid-state imaging device 30 are mounted on a common chip.

The solid-state imaging device 30 is supplied with the VDDH of one system from an internal power source. The VDDH is a first power voltage of a high potential. The regulator circuit 2 generates the VDDL from the VDDH. The VDDL is a second power voltage of a low potential. The VDDL is a power voltage of a potential level lower than the first power voltage.

The pixel array 31 includes pixels that are arranged in a matrix form. The pixel includes a photodiode serving as a photoelectric conversion element. The photoelectric conversion element generates signal charges according to a quality of incident light. The pixel accumulates the generated signal charges. The pixel array 31 operates using the VDDH as a power source.

The ADC 32 performs signal conversion from an analog signal to a digital signal. The signal conversion from the analog signal to the digital signal is referred to appropriately as “AD conversion.” The ADC 32 temporarily holds a signal that has been subject to the AD conversion. A portion dealing with an analog signal in the ADC 32 operates using the VDDH as a power source. A portion dealing with a digital signal in the ADC 32 operates using the VDDL as a power source.

The timing control circuit 33 generates a pulse signal used to control various kinds of timings. The pixel array 31 outputs the signal charges from a selected row of pixels to the ADC 32 according to a vertical scanning signal transmitted from the timing control circuit 33. The control signal transmitted from the timing control circuit 33 to the pixel array 31 is not illustrated. The timing control circuit 33 operates using the VDDL as a power source.

The transfer circuit 34 transfers the signal held in the ADC 32 to the outside of the solid-state imaging device 30. For example, the transfer circuit 34 transmits the signal to a memory outside the solid-state imaging device 30. The transfer circuit 34 operates using the VDDL as a power source. The transfer circuit 34 may transmit the signal to any configuration outside the solid-state imaging device 30 other than a memory.

The timing control circuit 33 transmits a vertical scanning signal to the ADC 32 and the transfer circuit 34. The ADC 32 performs the AD conversion according to the vertical scanning signal. The transfer circuit 34 reads the signal held in the ADC 32 in response to the vertical scanning signal. The VSS is not illustrated.

In the solid-state imaging device 30, data of various kinds of information is rewritten from the outside of the solid-state imaging device 30 using a communication device. The solid-state imaging device 30 receives various kinds of setting information related to imaging from the outside. The I/O circuit 6 receives the setting information input to the solid-state imaging device 30. The register circuit system holds various kinds of setting information of the solid-state imaging device 30.

The pixel array 31, the ADC 32, the timing control circuit 33, and the transfer circuit 34 operate according to data read from the low voltage register circuit 3. A level shifter (L/S) 35 converts a signal level of a logic signal input from the low voltage register circuit 3 to the pixel array 31. A level shifter (L/S) 36 converts a signal level of a logic signal input from the low voltage register circuit 3 to the ADC 32.

The solid-state imaging device 30 can switch an operation mode between an operation state serving as a first mode and a standby state serving as a second mode. The solid-state imaging device 30 images a subject image in the operation state. The solid-state imaging device 30 stops imaging of the subject image in the standby state.

Upon receiving the mode switching signal 11 from the outside in the operation state, the solid-state imaging device 30 switches the operation mode from the operation state to the standby state. The mode switching signal 11 is a signal to instruct the solid-state imaging device 30 to switch the operation mode.

The control circuit 5 receives the mode switching signal 11. Upon receiving the mode switching signal 11 in the operation state, the control circuit 5 transmits a control signal 15 to give an operation stop instruction to the regulator circuit 2. The regulator circuit 2 stops generation of the VDDL in response to the control signal 15. Thus, in the register circuit system, when the solid-state imaging device 30 is in the standby state, the operation of the regulator circuit 2 is stopped.

The supply of the VDDL to the low voltage register circuit 3, the control circuit 5, the I/O circuit 6, the ADC 32, the timing control circuit 33, and the transfer circuit 34 is interrupted. The supply of the VDDH to the solid-state imaging device 30 is continued in both the operation state and the standby state.

Since the supply of the VDDL to the low voltage register circuit 3 is interrupted, the data held in the low voltage register circuit 3 is lost. On the other hand, since the VDDH is continuously supplied, the high voltage register circuit 4 keeps holding the data and the address information. Thus, the register circuit system can maintain the setting information written before the solid-state imaging device 30 enters the standby state even during the standby state.

Upon receiving the mode switching signal 11 in the standby state, the control circuit 5 transmits a control signal 15 to give an operation resumption instruction to the regulator circuit 2. The regulator circuit 2 resumes the generation of the VDDL in response to the control signal 15. The supply of the VDDL to the low voltage register circuit 3, the control circuit 5, the I/O circuit 6, the ADC 32, the timing control circuit 33, and the transfer circuit 34 is resumed.

The control circuit 5 transmits the control signal 13 to the high voltage register circuit 4. The control circuit 5 transmits the control signal 14 to the low voltage register circuit 3 that is in the data writable state. The high voltage register circuit 4 transmits the transmission data 12 to the low voltage register circuit 3 in response to the control signal 13. The low voltage register circuit 3 receives the transmission data 12 from the high voltage register circuit 4 in response to the control signal 14. The register circuit system returns to the state in which data is being stored in the low voltage register circuit 3. Thus, the solid-state imaging device 30 resumes the operation according to a setting when it enters the standby state.

For example, the mode switching signal 11 is input to the solid-state imaging device 30 when a previously set period of time comes after the solid-state imaging device 30 starts imaging. In addition, the mode switching signal 11 may be input to the solid-state imaging device 30 according to an input operation performed by the user. The solid-state imaging device 30 may periodically switch the operation mode between the operation state and the standby state.

According to the second embodiment, the register circuit system can continuously hold data even when the operation of the regulator circuit 2 is stopped, similarly to the first embodiment. In the solid-state imaging device 30, when it returns from the standby state, time and effort to read the same information as the setting information read in the past from the outside can be saved. In the solid-state imaging device 30, compared to when the setting information is read from the outside, a time necessary for the return from the standby state can be reduced.

Accordingly, the register circuit system and the solid-state imaging device 30 have the advantage in that the current consumption can be reduced. The register circuit system and the solid-state imaging device 30 can achieve both maintenance of the setting information in the standby state and reduction in the current consumption.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A register circuit system, comprising:
a first register circuit configured to hold data, the first register circuit being supplied with a first power voltage;
a step-down circuit configured to generate a second power voltage of a potential level lower than the first power voltage from the first power voltage; and
a second register circuit configured to hold data, the second register circuit being supplied with the second power voltage from the step-down circuit,
wherein the first register circuit is configured to keep holding the data during a period of time in which the step-down circuit is stopping generation of the second power voltage.

2. The register circuit system according to claim 1,
wherein the register circuit system includes a control circuit configured to control operations of the step-down circuit, the first register circuit, and the second register circuit, and
the control circuit instructs the step-down circuit that is stopping generation of the second power voltage to resume the generation, and causes data of the same content as data being held in the first register circuit to be transmitted from the first register circuit to the second register circuit.

3. The register circuit system according to claim 1,
wherein a memory capacity of the first register circuit is smaller than a memory capacity of the second register circuit.

4. The register circuit system according to claim 1,
wherein the first register circuit stores data input from outside the register circuit system, and transmits data of the same content as the stored data to the second register circuit, and
the second register circuit stores the data received from the first register circuit.

5. The register circuit system according to claim 1,
wherein the first register circuit stores data input from outside the register circuit system and address information allocated to the data, and transmits transmission data including information of the same content as the stored data and the address information to the second register circuit, and
the second register circuit stores the data included in the transmission data at a position of an address indicated by the address information included in the transmission data.

6. The register circuit system according to claim 1,
wherein the first register circuit is supplied with the first power voltage while the step-down circuit is stopping the generation of the second power voltage.

7. The register circuit system according to claim 2,
wherein the control circuit uses the first power voltage as a power source, and transmits a control signal to instruct the resuming to the step-down circuit.

8. The register circuit system according to claim 2,
wherein the control circuit receives an input of a signal to instruct switching of an operation mode of the register circuit system, the operation mode including a first mode in which reading and writing of data in the register circuit system are performed and a second mode in which the reading and the writing are stopped, and
the control circuit transmits a control signal to instruct resuming the generation of the second power voltage to the step-down circuit in response to a signal to instruct switching of the operation mode from the second mode to the first mode.

9. The register circuit system according to claim 1,
wherein the control circuit receives an input of a signal to instruct switching of an operation mode of the register circuit system, the operation mode including a first mode in which reading and writing of data in the register circuit system are performed and a second mode in which the reading and the writing are stopped, and
the control circuit transmits a control signal to instruct a stop of the generation of the second power voltage to the step-down circuit in response to a signal to instruct switching of the operation mode from the first mode to the second mode.

10. A register circuit system, comprising:
a first register circuit configured to hold data, the first register circuit being supplied with a first power voltage;
a step-down circuit configured to generate a second power voltage of a potential level lower than the first power voltage from the first power voltage;
a second register circuit configured to hold data, the second register circuit being supplied with the second power voltage from the step-down circuit; and
a control circuit configured to control operations of the step-down circuit, the first register circuit, and the second register circuit,
wherein the control circuit controls generation of the second power voltage and interruption of generation of the second power voltage in the step-down circuit, and controls transmission of data to the second register circuit in the first register circuit, the data to be transmitted being data of the same content as the data being held by the first register circuit.

11. A solid-state imaging device, comprising:
a pixel array configured to include pixels arranged therein, each of the pixels including a photoelectric conversion element; and
a register circuit system configured to hold setting information related to imaging by the pixel array,
the register circuit system including
a first register circuit configured to hold data, the first register circuit being supplied with a first power voltage,
a step-down circuit configured to generate a second power voltage of a potential level lower than the first power voltage from the first power voltage, and
a second register circuit configured to hold data, the second register circuit being supplied with the second power voltage from the step-down circuit,
wherein the first register circuit is configured to keep holding the data during a period of time in which the step-down circuit is stopping generation of the second power voltage.

12. The solid-state imaging device according to claim 11,
wherein the solid-state imaging device includes a control circuit configured to control operations of the step-down circuit, the first register circuit, and the second register circuit, and
the control circuit instructs the step-down circuit that is stopping generation of the second power voltage to resume the generation, and causes data of the same content as data being held in the first register circuit to be transmitted from the first register circuit to the second register circuit.

13. The solid-state imaging device according to claim 11,
wherein a memory capacity of the first register circuit is smaller than a memory capacity of the second register circuit.

14. The solid-state imaging device according to claim 11,
wherein the first register circuit stores data input from outside the register circuit system, and transmits data of the same content as the stored data to the second register circuit, and
the second register circuit stores the data received from the first register circuit.

15. The solid-state imaging device according to claim 11,
wherein the first register circuit stores data input from outside the register circuit system and address information allocated to the data, and transmits transmission data including information of the same content as the stored data and the address information to the second register circuit, and
the second register circuit stores the data included in the transmission data at a position of an address indicated by the address information included in the transmission data.

16. The solid-state imaging device according to claim 11,
wherein the first register circuit is supplied with the first power voltage while the step-down circuit is stopping the generation of the second power voltage.

17. The solid-state imaging device according to claim 12,
wherein the control circuit uses the first power voltage as a power source, and transmits a control signal to instruct the resuming to the step-down circuit.

18. The solid-state imaging device according to claim 12,
wherein the control circuit receives an input of a signal to instruct switching of an operation mode of the solid-state imaging device, the operation mode including a first mode in which imaging is performed and a second mode in which imaging is stopped, and
the control circuit transmits a control signal to instruct resuming the generation of the second power voltage to the step-down circuit in response to a signal to instruct switching of the operation mode from the second mode to the first mode.

19. The solid-state imaging device according to claim 11,
wherein the control circuit receives an input of a signal to instruct switching of an operation mode of the solid-state imaging device, the operation mode including a first mode in which imaging is performed and a second mode in which imaging is stopped, and
the control circuit transmits a control signal to instruct a stop of the generation of the second power voltage to the step-down circuit in response to a signal to instruct switching of the operation mode from the first mode to the second mode.
